(19) United States
(12) Patent Application Publication
(10) Pub. No.: US 2023/0116340 A1
(43) Pub. Date: Apr. 13, 2023

(54) METHOD OF MANUFACTURING WIRELESS CHARGING COIL MODULE COATED WITH MAGNETIC MATERIAL ON SURFACE OF COIL

(71) Applicant: WITS Co., Ltd., Yongin-si (KR)

(72) Inventors: Du Hyun SONG, Suwon-si (KR); Seung Jae BAECK, Suwon-si (KR); Chun Su YOON, Suwon-si (KR); Jeong Yub YANG, Suwon-si (KR); Dong Hyun KIM, Suwon-si (KR); Yong Gu YOON, Suwon-si (KR); Ji Hoon YEOM, Suwon-si (KR)

(73) Assignee: WITS Co., Ltd., Yongin-si (KR)

(21) Appl. No.: 17/684,717

(22) Filed: Mar. 2, 2022

(30) Foreign Application Priority Data
Oct. 8, 2021 (KR) 10-2021-0133663
Dec. 9, 2021 (KR) 10-2021-0176137

(51) Int. Cl. H01F 41/04; H01F 41/02; G03F 7/00

(52) U.S. Cl. CPC H01F 41/041; H01F 41/0206; G03F 7/00; H02J 50/10

(57) ABSTRACT

Disclosed is a method of manufacturing a coil module that receives or transmits electric power or signals wireless by using an electromagnetic field. The method includes preparing a substrate, forming a coil on the substrate, and forming a magnetic part covering at least a portion of the coil while directly contacting a surface of the coil, and that acts as an electromagnetic booster that enhances an intensity of the electromagnetic field generated on the surface of the coil, and the magnetic part is formed through at least one of electroless plating, electro-plating, deposition, and printing.

### CROSS-REFERENCE TO RELATED APPLICATIONS

This application claims priority under 35 U.S.C. § 119 to Korean Patent Applications No. 10-2021-0133663 filed on Oct. 8, 2021 and No. 10-2021-0176137 filed on Dec. 9, 2021, in the Korean Intellectual Property Office, the disclosures of which are incorporated by reference herein in their entireties.

### BACKGROUND

Embodiments of the inventive concept relate to a method of manufacturing a coil module coated with a magnetic material on a surface of a coil.

In recent years, a wireless power transfer (WPT) function, a near field communication (NFC) function, a magnetic secure transmission (MST) function, and the like have been employed in mobile portable devices. The WPT, NFC, and MST technologies are different in operation frequencies, data transmission rates, electric energy transmitted, and the like.

In a wireless power transmission device, various forms of coils are used, and the WPT, NFC, and MST technologies are implemented by using a magnetic field and an electric field formed by the coils.

Recently, as requirements for small sizes and multiple functions of electronic device have been increased, wireless charging modules and magnetic sheets included therein need to be small-sized, and demands on coil modules having an excellent heat dissipation performance in addition to transmission of signals and electric power at high efficiency are increased as well.

### SUMMARY

Embodiments of the inventive concept provide a method of manufacturing a wireless charging coil module that has a high wireless charging efficiency while showing an excellent heat dissipation effect when low, middle, or high electric power is wirelessly transmitted and received for a long time.

According to an embodiment of the inventive concept, a method of manufacturing a coil module that receives or transmits electric power or signals wireless by using an electromagnetic field includes preparing a substrate, forming a coil on the substrate, and forming a magnetic part covering at least a portion of the coil while directly contacting a surface of the coil, and that acts as an electromagnetic booster that enhances an intensity of the electromagnetic field generated on the surface of the coil, wherein the magnetic part decrease, among a skin effect of an eddy current and a proximity effect generated in the coil, the proximity effect by isolating electric power in a gap of the coil that is rotated in the one direction.

According to an embodiment of the inventive concept, the forming of the magnetic part may be performed through at least one of electroless plating, electro-plating, deposition, coating, and printing.

According to an embodiment of the inventive concept, when the magnetic part is formed through the at least one of the electroless plating, the electro-plating, the deposition, the coating, and the printing, masking a coil area, except for an area, in which the magnetic part is to be formed, may be performed in advance before the forming of the magnetic part.

According to an embodiment of the inventive concept, when the magnetic part is formed through the electro-plating, a current may be applied to only the area, in which the magnetic part is to be formed.

According to an embodiment of the inventive concept, the method may further include polishing the magnetic part formed on an upper surface of the coil to remove the magnetic part.

According to an embodiment of the inventive concept, the forming of the coil and the forming of the magnetic part may be performed in a single process.

According to an embodiment of the inventive concept, the forming of the coil and the magnetic part may include forming a conductive film on the substrate, forming a photosensitive film on the conductive film, forming a photosensitive film pattern by exposing and developing the photosensitive film, and forming the coil by etching the conductive film while the photosensitive film pattern is taken as a mask. Here, the method may further include forming the magnetic part on the substrate, and lifting off the photosensitive film pattern and the magnetic part on the photosensitive film pattern.

According to an embodiment of the inventive concept, the photosensitive film may be provided as a dry film type photoresist.

According to an embodiment of the inventive concept, the method may further include removing the substrate from the coil and the magnetic part, and transferring the coil and the magnetic part onto a separate substrate.

According to an embodiment of the inventive concept, at least one of the forming of the coil and the forming of the magnetic part may be performed in a Reel to Reel scheme and/or a panel-to-panel scheme

According to an embodiment of the inventive concept, the coil may be a wire, of which a cross-section that is perpendicular to a lengthwise direction thereof is circular.

According to an embodiment of the inventive concept, the magnetic part may cover at least a portion of an upper surface and a side surface of the coil.

According to an embodiment of the inventive concept, the magnetic part provided between adjacent portions of the coil may have a spacing part between the adjacent portions of the coil.

According to an embodiment of the inventive concept, a cross-section that is perpendicular to a lengthwise direction of the coil may have a wire shape, and the magnetic part may cover an entire outer peripheral surface of the coil.

According to an embodiment of the inventive concept, a cross-section that is perpendicular to a lengthwise direction of the coil has a quadrangular shape.

According to an embodiment of the inventive concept, in the coil arranged in the first direction, the magnetic part may be provided alternately.

According to an embodiment of the inventive concept, the magnetic part may include at least one of a metal pallet, a nano crystal, an amorphous material, a metal-based or ferrite pellet, a ferrite complex, a sendust pallet, and a sendust complex.

According to an embodiment of the inventive concept, the magnetic part may include a combination of two or three or more elements selected from a group consisting of Fe, Ni, Co, Mn, Al, Zn, Cu, Ba, Ti, Sn, Si, Sr, P, B, N, C, W, Cr, Bi, Li, Y, and Cd.

According to an embodiment of the inventive concept, the magnetic part may include Fe, Ni, Mn, and C.

According to an embodiment of the inventive concept, the magnetic part may further include Si and B as impurities.

According to an embodiment of the inventive concept, the substrate may be a rigid printed circuit board, a flexible printed circuit board, or a rolled copper printed circuit board.

According to an embodiment of the inventive concept, the coil may be provided as a winding, and the coil includes at least one of a copper coil, a multiline coil, a laminated ceramic condenser coil, a low-temperature simultaneous co-fired ceramic coil, and a ceramic winding coil.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a perspective view schematically illustrating an external appearance of a wireless charging system according to an embodiment of the inventive concept;

FIG. 2 is an exploded cross-sectional view schematically illustrating main internal configurations of FIG. 1.

FIG. 3 is a plan view illustrating a coil module according to an embodiment of the inventive concept;

FIG. 4 is a plan view illustrating a coil module according to an embodiment of the inventive concept.

FIG. 5 illustrates two coil parts in a coil module according to an embodiment of the inventive concept;

FIG. 6 illustrates a shape of a coil according to an embodiment of the inventive concept;

FIG. 7 is a cross-sectional view taken along a line A-A′ of FIG. 3;

FIGS. 8A to 8E, 9A, and 9B are cross-sectional views illustrating a shape of a first spiral coil according to embodiments of the inventive concept;

FIGS. 10A and 10B are cross-sectional views schematically illustrating a method of manufacturing a coil module according to an embodiment of the inventive concept;

FIGS. 11A to 11D illustrate various shapes that may be manufactured when a magnetic part is formed through plating;

FIGS. 12A to 12D are cross-sectional views schematically illustrating an operation of forming a coil part by using a photosensitive film;

FIGS. 13A and 13B are cross-sectional views schematically illustrating a part of an operation of forming a coil part by using a photosensitive film;

FIG. 14 is a cross-sectional view schematically illustrating a method of forming a coil part by using transfer; and

FIGS. 15A and 15B conceptually disclose that a process is performed in a Reel to Reel scheme or a panel-to-panel scheme.

### DETAILED DESCRIPTION

The following terms are considered to be well understood by an ordinary person in the art, but the following definitions are described to easily explain the essence of the inventive concept disclosed herein.

Unless defined otherwise, all the technical and scientific terms used herein have the same meanings as those generally understood by an ordinary person in the art, to which the essence of the inventive concept disclosed herein pertains. Arbitrary methods, devices, and materials that are similar to or equivalent to those described herein may be used to a performance or inspection of the essence of the inventive concept described herein, but representative method, device, and material will be described now.

The inventive concept relates to a method of manufacturing a coil module including an antenna or a coil used for transmitting or receiving electric power or signals by using an electromagnetic field, and more particularly, to a method of manufacturing a coil module that minimizes a proximity effect by directly coating a magnetic part on a surface of a coil. The coil is used as an antenna and may be referred to as an antenna, but in any case, will be referred to as a coil for convenience of description herein.

In an embodiment of the inventive concept, the coil module may be used in a wireless charging device, but is not limited thereto and may be used for various transmissions/receptions of signals. For convenience of description, a coil used for a wireless charging device will be mainly described hereinafter, but the inventive concept is not limited thereto, and the purposes thereof will be variously changed within a limit of the inventive concept.

Hereinafter, a preferred embodiment of the inventive concept will be described in detail with reference to the accompanying drawings.

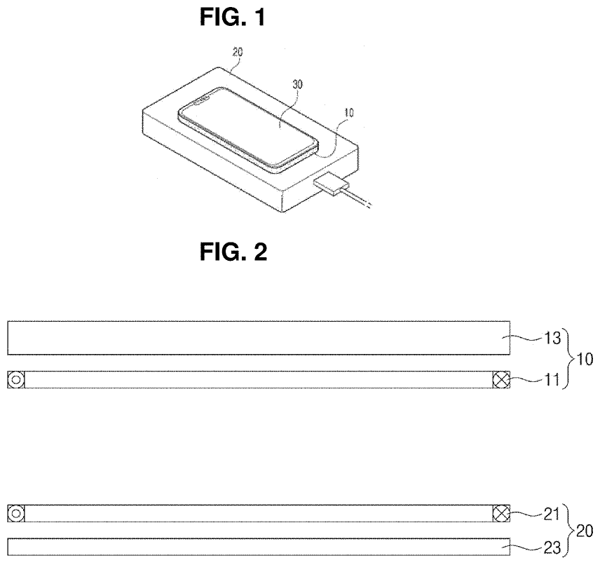

FIG. 1 is a perspective view schematically illustrating an external appearance of a wireless charging system according to an embodiment of the inventive concept. FIG. 2 is an exploded cross-sectional view schematically illustrating main internal configurations of FIG. 1.

Referring to FIGS. 1 and 2, a wireless charging system may include a wireless power transmitting device 20 and a wireless power receiving device 10. The wireless power receiving device 10 may include various electronic devices 30 such as a mobile phone, a notebook, and a table PC.

The wireless power receiving device 10 may include a battery 13, and a reception part coil module 11 for charging the battery 13 by supplying electric power to the battery 13.

The battery 13 may be a nickel hydrogen battery or a lithium ion battery that may be charged or discharged. Furthermore, the battery 13 may be implemented to be provided separately from the wireless power receiving device 10 to be attached to or detached from the wireless power receiving device 10, or may be implemented of an integral type to be integrally formed with the battery 13 and the wireless power receiving device 10.

The wireless power transmitting device 20 is adapted to charge the battery 13 of the wireless power receiving device 10, and may include a device substrate and a transmission part coil module 21 in an interior thereof. The transmission part coil module 21 may be provided on the device substrate.

The wireless power transmitting device 20 may convert AC power supplied from an outside to DC power, and in turn may convert the DC power to an AC voltage of a specific frequency to provide the AC voltage to the wireless power receiving device 10. A magnetic field of the transmission part coil module 21 is changed when the AC voltage is applied to the transmission part coil module 21 in the wireless power transmitting device 20. When a magnetic field formed by the transmission part coil module 21 is changed, a magnetic field in the reception part coil module 11 of the wireless power receiving device 10 also is changed, and the battery 13 is charged as a voltage is applied according to the change in the magnetic field in the reception part coil module 11.

The transmission part coil module 21 and the reception part coil module 11 may be electromagnetically coupled to each other. The transmission part coil module 21 and the reception part coil module 11 may include a coil formed by winding a metal wire such as a copper wire on a plane. In this case, a winding shape of the coil may be a circular shape, a quadrangular shape, and a rhombus shape, and the entire size or the number of windings thereof may be properly controlled according to required characteristics.

A magnetic sheet may be additionally disposed between the reception part coil module 11 and the battery 13 and/or between the transmission part coil module 21 and the device substrate. Then, the magnetic sheet may be located between the reception part coil module 11 and the battery 13 to collect magnetic fluxes, and thus the magnetic fluxes may be received by the reception part coil module 11. In addition, the magnetic sheet functions to interrupt at least some of the magnetic fluxes from reaching the battery 13.

In an embodiment of the inventive concept, the coil may be used for magnetic secure transfer (MST), near field communication (NFC), and the like, in addition to the wireless charging device. This will be described later.

Hereinafter, both of the transmission part coil module 21 and the reception part coil module 11 will be referred to as coil modules when it is not specifically distinguish them, and the reception part coil module will be described as an example in the following embodiments.

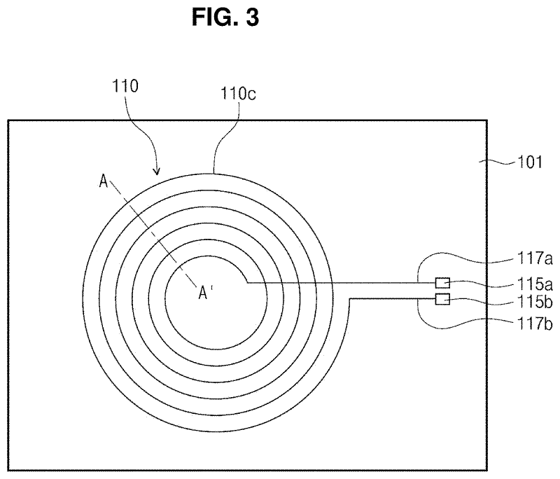

FIG. 3 is a plan view illustrating a coil module according to an embodiment of the inventive concept.

Referring to FIG. 3, the electronic device (for example, a wireless charging device) includes a coil module that receives or transmits electric power or signals by using an electromagnetic field, and the coil module includes a coil part 110 provided on at least one surface of a substrate 101.

The substrate 101 has a flat plate shape (or a sheet shape), and is disposed on one side of the coil part 110. The coil part 110 may be provided directly on one surface of the substrate 101 or may be provided on one surface of the substrate 101 while another element such as an adhesive being interposed therebetween. Hereinafter, the coil part 110 provided on one surface of the substrate 101 is described as an example, but the relationship between the coil part 110 and the substrate 101 is not limited thereto, and coil parts 110 may be provided on opposite surfaces of the substrate 101.

The substrate 101 may be formed of a material having a heat-resistant property and a pressure-resistant property. The substrate 101 may be a magnetic material. That is, the substrate 101 may have a form of a magnetic sheet. The magnetic sheet is provided to efficiently form a magnetic path of the magnetic field generated by a coil 111. To achieve this, the magnetic sheet also may be formed of a material that may easily form a magnetic path. The magnetic sheet may be a ferrite sheet. However, the magnetic sheet has a magnetism and is not limited only to the ferrite sheet, and may be at least one of a ferrite sheet, a soft ferrite metal sheet, and a hybrid type sheet, to which a metal and a ferrite is complexly applied. Furthermore, the magnetic sheet may be a thin sheet that is manufactured by making a metal thin film thinner and distributing and pressing on an insulating resin. Various ferrite material compositions may be used, and for example, Fe, Fe—Si, Fe—Al—Si, Fe—Ni, and Fe—Co may be used, and various materials other than a ferrite may be used so long as they are magnetic materials.

The substrate 101 may be formed of other insulating materials. For example, the substrate 101 may be formed of a polymer material such as an epoxy resin. However, the material of the substrate 101 is not limited thereto, and the substrate 101 may be a printed circuit board (PCB), a ceramic board, a pre-molded board, or a direct bonded copper (DBC) board, or may be an insulating metal substrate (IMS). However, the material of the substrate 101 is not limited thereto, and various insulating materials. When the substrate 101 is formed of a material other than the magnetic material, a separate magnetic sheet may be additionally provided between the substrate 101 and the battery. In this case, the additional magnetic sheet is used both to efficiently form a magnetic path of a magnetic field and to interrupt a magnetic path in a direction of the battery.

According to the present embodiment, the substrate 101 may be rigid, but the inventive concept is not limited thereto, and may be soft, that, flexible. The rigid or flexible substrate may be provided in various forms, and for example may be provided as a rigid printed circuit board, a flexible printed circuit board, or a rolled copper printed circuit board that may be used as a lead frame.

The coil part 110 may be provided on at least one surface of the substrate 101 in a form of a wiring line. That ism, the coil part 110 may be provided on a plane defined by one surface of the substrate 101, on at least one surface of the substrate 101, and may include a spiral coil 110c having a spiral shape.

The spiral coil 110c may include a coil 111 formed of a conductor, for example, a metal, and a magnetic part 113 that covers at least a portion of the coil 111. The coil part 110 also may include first and second extraction parts 117a and 117b provided at opposite ends of the coil 11 to extend to an outside of the spiral coil 110c, and first and second terminal parts 115a and 115b provided at ends of the first and second extraction parts 117a and 117b to be connected to other configurations (for example, a circuit part). In the present embodiment, it is illustrated that the first and second terminal parts 115a and 115b are provided in the quadrangular substrate 101, but the inventive concept is not limited thereto, and they may extend for electrical connection to the outside and protrude from one side of the substrate 101. The first and second terminal parts 115a and 115b may include a plurality of connection terminals.

In the present embodiment, the coil 111 may be a circular, elliptical, or polygonal flat coil that is wound in a clockwise or counterclockwise direction. The shape of the coil 111 is not limited to the drawing, and may be in a form of a winding. The coil may be a coil in a form of a Litz wire having several strands or a polyurethane enameled wire (UEW). In an embodiment of the inventive concept, the material of the coil also is not limited thereto, and may be formed of a material including copper or ceramic. The kinds of the coil may include the Litz wire or the UEW wire as a copper coil, which has been described above, and a laminated ceramic condenser coil (MLCC) or a low-temperature co-fired ceramic coil (LTCC) as a ceramic contained winding coil material.

In the present embodiment, the coil 111 may be disposed in a spiral form, starting from a central portion of the substrate 101. Then, according to the embodiment, a rotational direction of the coil 111 may be provided to be rotated spirally from an inner side to an outer side. Although it is illustrated that the coil 111 has a circular spiral shape in the drawing, the inventive concept is not limited thereto, and any spiral shape that may be rotated to generate resonances in the same current direction may be applied.

The above-described coil 111 may function as the coil 111 for wireless power transfer (WPT) when transmission of electric power is required, may function as the coil 111 for magnetic secure transmission (MST) when magnetic information has to be transmitted wirelessly, and may be provided as the coil 111 for near field communication (NFC). Although it has been described as an example in the present embodiment that the coil 111 performs multiple functions, the inventive concept is not limited thereto, and the coil 111 may include the coil 111 for WPT that performs a power transmission function.

The coil 111 may be provided only on a front surface of the substrate 101, or coils 111 may be provided on both the front surface and a rear surface thereof. When the coils 111 is provided on both the front surface and the rear surface, the two coils 111 may be electrically separated from each other, or at least portions thereof may be connected to each other through a via to be electrically connected to each other. In other words, when the coils 111 are formed on opposite surfaces of the substrate 101, opposite ends of each of the coils 111 may be connected to each other such that the coils 111 constitutes a parallel circuit, or ends at the centers thereof may be connected to each other to constitute a series circuit. To achieve this, a conductive via (not illustrated) for electrically connecting the coils 111 may be formed in interiors of the coils 111.

Here, at least one of the first and second extraction parts 117a and 117b may be disposed while an insulator that is separate from a crossing wiring line to prevent a short circuit with the crossing wiring line being interposed between the at least one of the first and second extraction parts 117a and 117b and the crossing wiring line, or may be connected to the wiring line through a wiring line provided on another surface through a via.

The above-described structure of the coil module has been described as an example, and in the embodiment of the inventive concept, connection relationships thereof and the number or a disposition of the coils 111 may be modified in various forms.

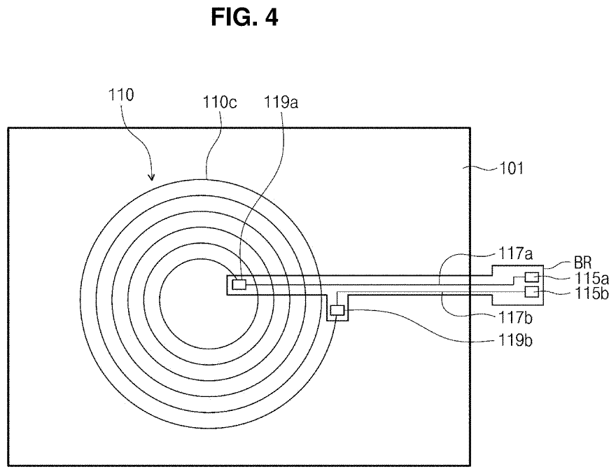

FIG. 4 is a plan view illustrating a coil module according to an embodiment of the inventive concept.

Referring to FIG. 4, according to the coil module according to the embodiment of the inventive concept, the extraction parts and terminal parts connected to the opposite ends of the coil part 110 may be manufactured separately to be connected. That is, the coil 111, and the first and second extraction parts 117a and 117b and the first and second terminal parts 115a and 115b connected to the opposite ends of the coil 111 may not be disposed on the substrate 101 like the spiral coil 110c, but may made as a bridge BR that is a separate configuration separated from the substrate 101 to be attached to the substrate 101. Here, first and second pad parts (not illustrated) are provided at the opposite ends of the coil 111. The bridge BR may include first and second bridge pads 119a and 119b corresponding to the first and second pad parts of the opposite ends of the coil 111, the first and second extraction parts 117a and 117b connected to the first and second bridge pads 119a and 119b, respectively, and the first and second terminal parts 115a and 115b connected to the first and second extraction parts 117a and 117b. The first and second bridge pads 119a and 119b, the first and second extraction parts 117a and 117b, and the first and second terminal parts 115a and 115b may be formed on the bridge substrate, and the bridge substrate may be a rigid or flexible substrate.

The first and second bridge pads 119a and 119b may be connected to the first and second pad parts of the coil 111 by a conductor. As an example, the first and second bridge pads 119a and 119b and the first and second pad parts of the coil 111 may be connected to each other through soldering using heat, ultrasonic waves, laser beams, or the like, but the inventive concept is not limited thereto, and they may be variously joined to each other, for example, by using an amorphous conductive film.

Here, the configuration of the bridge BR is an example for electrically connecting the opposite ends of the coil 111 to another configuration, and the inventive concept is not limited thereto and may be modified in various forms.

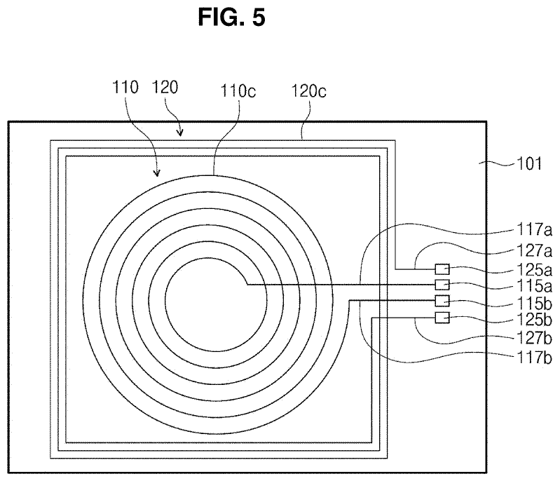

FIG. 5 illustrates two coil parts in a coil module according to an embodiment of the inventive concept.

In the present embodiments, to distinguish different coil parts, the coil part described in the above-described embodiment is described as the first coil part 110 and an added coil part is described as a second coil part 120, and an aspect that is different from that of the above-described embodiment will be mainly described for convenience of description.

In the embodiment of the inventive concept, the coil module may include the first coil part 110 provided on at least one surface or the substrate 101 and having a spiral shape, and the second coil part 120 provided on at least one surface of the substrate and disposed on an outside of the first coil part 110.

The first coil part 110 includes the first and second extraction parts 117a and 117b and the first and second terminal parts 115a and 115b connected to the first spiral coil 110c, and the second coil part 120 includes first and second extraction parts 127a and 127b and first and second terminal parts 125a and 125b connected to the second spiral coil 120c.

Subsequently, the second spiral coil 120c is provided on at least one surface of the substrate 101, and is disposed on an outside of the first spiral coil 110c to have a shape that surround the first spiral coil 110c as a whole. Although it is illustrated in the present embodiment that the second spiral coil 120c has separate extraction parts and terminal parts, the inventive concept is not limited thereto, and one end of the second spiral coil 120c may be connected to the first coil and an opposite end thereof may be connected to the terminal part.

The second spiral coil 120c is disposed at an outskirt of the first spiral coil 110c as a whole, but the inventive concept is not limited thereto, and at least a portion thereof may be provided to cross the first spiral coil 110c.

In the embodiment of the inventive concept, the second spiral coil 120c may function as a coil for MST when it is necessary to wirelessly transmit magnetic information, and may be used as a coil for NFC for near field wireless communication.

In the embodiment of the inventive concept, when a frequency band of the second spiral coil 120c is higher than a frequency band of the first spiral coil 110c, the second spiral coil 120c may have a conductive pattern of a line width that is smaller than that of the first spiral coil 110c, and an interval of wiring thereof may be smaller than that of the first spiral coil 110c.

In the embodiment of the inventive concept, the coil module may have various shapes.

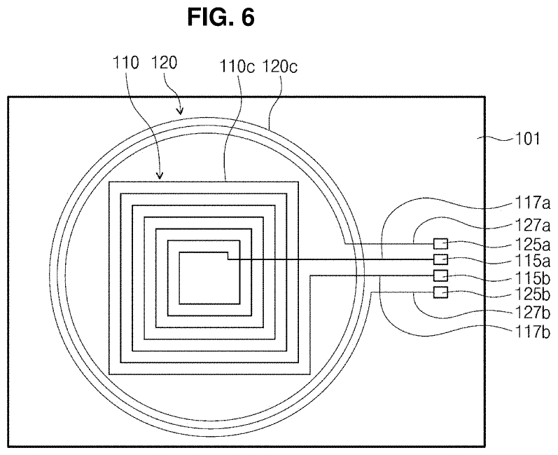

FIG. 6 illustrates a shape of the coil according to the embodiment of the inventive concept, and unlike FIG. 5, discloses that the first spiral coil 110c and the second spiral coil 120c have shapes, in which spiral arrangements thereof on a plane are different.

Referring to FIG. 6, the first spiral coil 110c has one quadrangular shape when viewed on a plane, and the second spiral coil 120c has a circular shape of a spiral shape at an outskirt of the first spiral coil 110c. The above-described embodiment of FIG. 5 is different from the present embodiment in that the first spiral coil 110c has a circular shape and the second spiral coil 120c has a quadrangular shape. In this way, the first spiral coil 110c and the second spiral coil 120c may have different shapes, and may be variously modified without departing from the inventive concept even though not illustrated here.

In FIGS. 5 and 6, the first spiral coil 110c and the second spiral coil 120c may be independently used as any one of a coil for WPT, a coil for NFC, and a coil for MST. A combination of the first spiral coil 110c and the second spiral coil 120c, for example, may be used for a coil for WPT and a coil for NFC, a coil for MST and a coil for WPT, or a coil for MST and a coil for NFC. However, the purpose of the coil is not limited thereto, and it is apparent that the coil may be used for another purpose and a coil that is not disclosed may be further added.

According to the embodiment of the inventive concept, in the above-described various coil modules, the coil part includes a magnetic part that acts as an electromagnetic booster that improves an intensity of an electromagnetic field generated on a surface of the coil. This will be described in detail as follows.

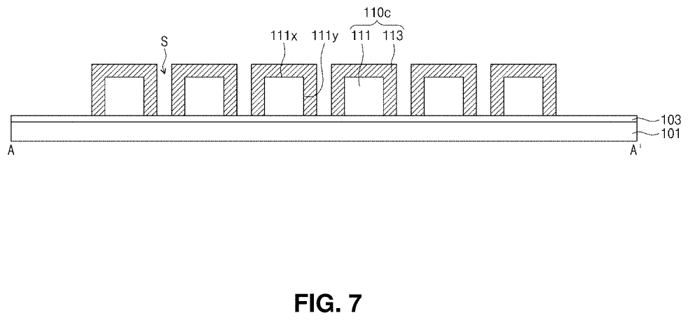

FIG. 7 is a cross-sectional view taken along a line A-A′ of FIG. 3, and is a cross-sectional view illustrating a shape of the coil part.

Referring to FIGS. 3 and 7, the coil module includes the substrate 101, and the coil part 110 provided on at least one surface of the substrate 101, and an insulation part 103 may be provided between the substrate 101 and the coil part 110.

The insulation part 103 is provided in a form of a membrane or a film between the substrate 101 and the coil part 110, and any material that may insulate the substrate 101 and the coil part 110 may be used for the insulation part 103 without limitation, and the insulation part 103 may be formed of various materials. For example, the insulation part 103 may include an organic insulation film, an inorganic insulation film, or an insulation film formed of an organic-inorganic ionic thermocouple composite material.

The magnetic part 113 may directly contact the coil 111 and may cover at least a portion of an exposed surface of the coil 111. The magnetic part 113 may be formed on a surface of the coil 111 through a process such as plating, deposition, or coating.

The magnetic part 113 is provided to increase a wireless charging efficiency in the transmission/reception coil 111 of the wireless charger and lower a heat emission temperature in the charger. To achieve this, the magnetic part 113 needs to directly contact the coil 111, and at least a portion of the magnetic part 113 directly contacts the coil 111. When another configuration is interposed between the magnetic part 113 and the coil 111, an effect and a heat dissipation effect of the following magnetic material may be decreased.

The magnetic material has a high permeability, and the magnetic material is provided on the coil 111 to function to strongly boost an intensity of an electromagnetic field generated on a surface of the coil 111. It appears that the phenomenon occurs because permeability is enhanced, permeation loss is lowered, and a frequency bandwidth for use of wireless charging is enhanced by adding a high magnetic material on the coil 111, and accordingly, it is determined that wireless charging efficiency is increased and a surface density of the electromagnetic field generated in the wireless charging coil 111 is further concentrated on the surface or the metal coil 111.

The magnetic part 113 may be formed of a magnetic material. For example, the magnetic material constituting the magnetic part 113 may be a metal pallet, a nano crystal, an amorphous material, a metal-based or ferrite pellet, a ferrite complex, a sendust pallet, and a sendust complex. The material of the magnetic material is not specifically limited.

In the embodiment of the inventive concept, the magnetic part 113 may include an alloy magnetic material or a ferrite magnetic material including a combination of two or three or more elements selected from a group consisting of Fe, Ni, Co, Mn, Al, Zn, Cu, Ba, Ti, Sn, Si, Sr, P, B, N, C, W, Cr, Bi, Li, Y, and Cd. In the magnetic part 113, a permeability of the magnetic material manufactured through a process of heat-treating or mixing the materials may be controlled. In particular, a permeability Ur of the product may be changed through a process of heat-treating or mixing the materials including Fe, Ni, Mn, Si, B, and C. In the embodiment of the inventive concept, particularly, main substances of the magnetic part 113 may be Ni and Fe, and the permeability Ur and a magnetic flux density Bs may be controlled by adjusting a content of Fe. Furthermore, the magnetic part is a soft magnetic material, and a coercive force thereof may be controlled by adjusting contents of Ni and Fe. In the embodiment of the inventive concept, in addition to the materials of the magnetic part 113, Si and/or B may be added as impurities.

A permeability and a permeation loss of the wireless transmitting/receiving device may vary according to a thickness of the magnetic part 113, and the thickness of the magnetic part 113 may be about 0.01 μm to about 80 μm in the embodiment, may be about 0.1 μm to about 40 μm in another embodiment, and may be about 1 μm to about 5 μm in another embodiment. In the present embodiment, when the magnetic part 113 on an upper surface 111x of the coil 111 is thick, an intensity of the magnetic field in an upward direction may be lowered, and in this case, it may be difficult to transmit signals or electric power. Accordingly, a thickness of the upper surface 111x of the coil 111 may have the above-described values. However, in this case, the values may be changed according to a state or a structure, or other factors of the coil 111. In the present embodiment, a permeability of the magnetic part 113 may be about 50μ′ to about 3000μ′ in one embodiment, and may be about 100μ′ to about 2000μ′ in another embodiment.

The coil 111 may have various shapes when viewed on a cross-section thereof. In the embodiment of the inventive concept, the coil 111 has a circular shape, but may have various polygonal shapes that contact the substrate 101 or the insulation part 103 on the substrate 101. For example, a cross-section of the coil 111 may have a quadrangular shape (a rectangular shape or a trapezoidal shape). However, the shape of the coil 111 is not limited thereto.

In the embodiment of the inventive concept, the magnetic part 113 may cover at least some of the upper surface 111x, a side surface 111y, and a lower surface of the coil 111, and for example, may cover both of the upper surface 111x and the side surface 111y of the coil 111, cover at least one of the upper surface 111x and the side surface 111y, and cover only at least a portion of the upper surface 111x and the side surface 111y if necessary. Furthermore, the lower surface of the coil 111 may be covered if necessary.

In the present embodiment, the magnetic part 113 may cover both of the upper surface 111x and the side surface 111y of the coil 111. Here, a spacing part “S” may be provided in a space between the coils 111, which is covered by the magnetic part 113. In this case, the spacing part may be provided with an insulator such that the adjacent two coils 110c are sufficiently insulated. The insulator may be provided to present a short-circuit of the adjacent two magnetic parts 113. For example, the spacing part may be provided with air.

In the embodiment of the inventive concept, the spacing part may be provided with another additional insulation part, in addition to the air.

When the insulation part 103 between the coil 111 and the substrate 101 is the first insulation part 103 and the insulation part provided on the spiral coil 110c is the second insulation part for convenience' sake, the first and second insulation parts may be formed of various insulating materials, for example, a polymer resin. The second insulation part may be provided between the adjacent spiral coils 110c and on an upper side of the spiral coils 110c to cover both of the spiral coils 110c. The materials that constitute the first and second insulation parts are not limited thereto, and may be the same or different.

According to the embodiment of the inventive concept, the coil 111 of the coil module according to the embodiment of the inventive concept is divided into a plurality of parts and a surface thereof is divided into a plurality of areas, and a skin effect is maximized by providing a wiring line covered with a magnetic material on the surface thereof. Furthermore, a proximity effect of the adjacent wiring lines is alleviated through the structure having the plurality of divided parts. That is, the magnetic part alleviates, among a skin effect and a proximity effect of an eddy current generated in the coil, the proximity effect, and this is achieved through a method of isolating electric power between the coils that are rotated in one direction by using a magnetic material. In this way, when the skin effect is increased and the proximity effect is decreased, the eddy current effect is minimized whereby the wireless charging efficiency is increased and emission of heat is reduced as well.

Through this, the coil module according to the embodiment of the inventive concept may has a high wireless charging efficiency while showing an excellent heat dissipation effect when low, middle, and high electric power is wirelessly transmitted and received for a long time.

That is, when being used as a wireless charging transmission/reception coil, the coil module according to the embodiment of the inventive concept having the above structure functions to strongly boost an intensity of an electromagnetic field by adding a magnetic material having a high permeability on a surface of the wireless charging transmission/reception coil. Because a high magnetic material is added to an interior of the wireless charger, permeability is enhanced, permeation loss is lowered, and a bandwidth of a frequency for use of wireless charging is enhanced, and as a result, a wireless charging efficiency is increased. Here, a surface density of the electromagnetic field generated by the wireless charging transmission/reception coil is further concentrated on the surface of the coil.

In the existing invention, a magnetic sheet is provided at a lower portion of the coil 111 and a structure, in which heat dissipation sheets, for example, graphite as a material for dissipation of heat, are stacked separately from the magnetic sheet. In the stack structure, the magnetic sheets function as gates for passing an electromagnetic field radiated from the metal coil 111 through a magnetic layer, and this functions to activate a horizontal electromagnetic field. However, in the inventive concept, because the coil 111 covers the horizontal electromagnetic field due to the magnetic material at a central portion thereof and the magnetic material as well, the covered magnetic material is operated as an electromagnetic booster that further activates the electromagnetic field formed by the coil 111.

In the embodiment of the inventive concept, a shape of the first spiral coil 110c of the coil part 110, in particular, shapes of the coil 111 and the magnetic material may be changed in various forms.

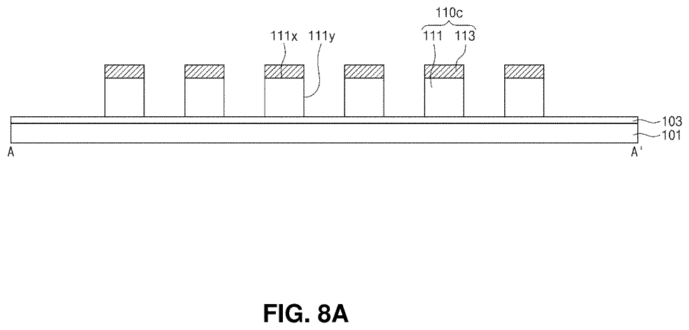

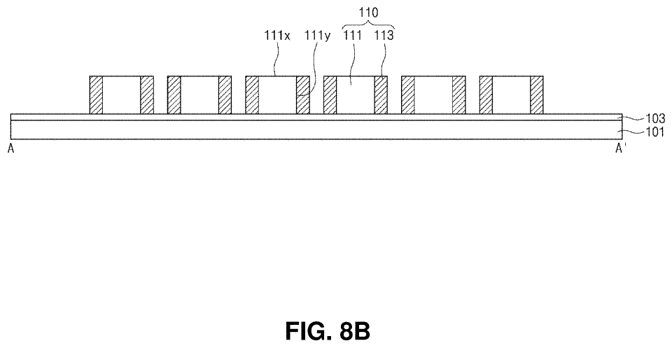

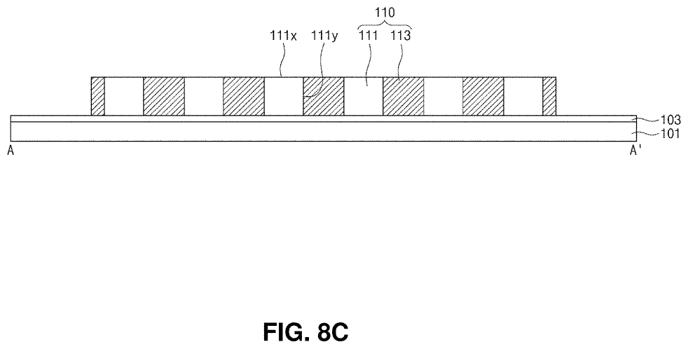

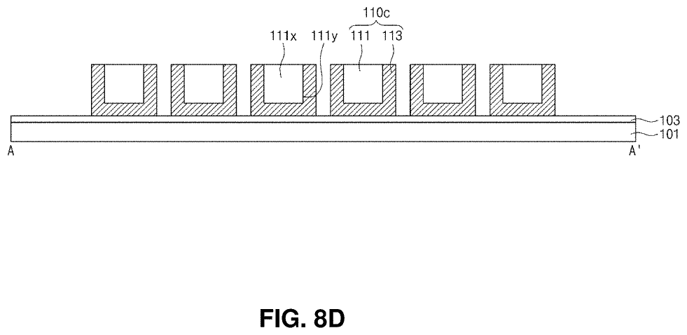

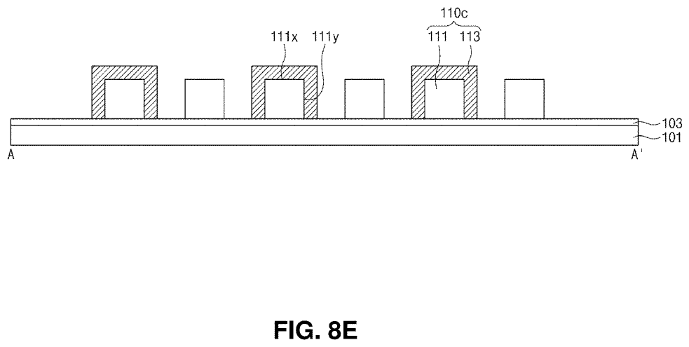

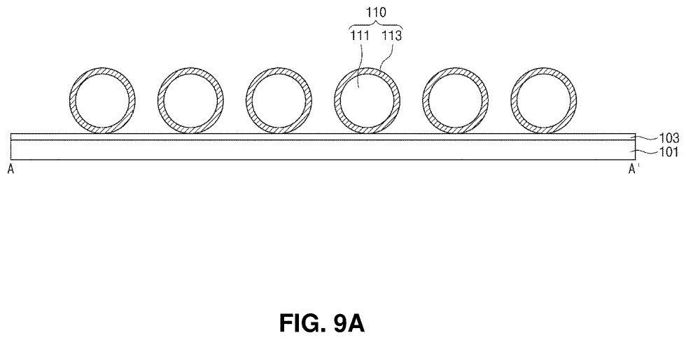

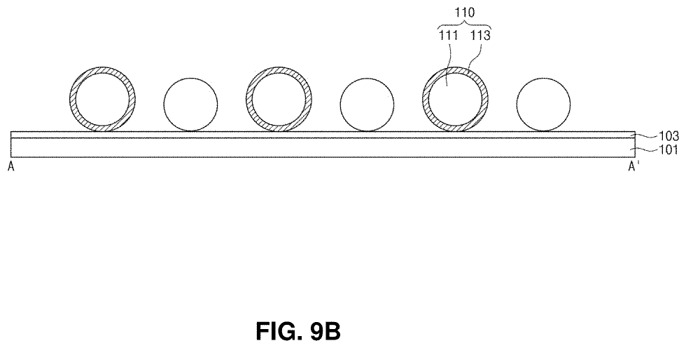

FIGS. 8A to 8E, 9A, and 9B are cross-sectional views illustrating the shape of the first spiral coil 110c according to embodiments of the inventive concept.

Referring to FIGS. 8A to 8E, the magnetic part 113 may be provided only on the upper surface 111x of the coil 111 as illustrated in FIG. 8A, may be provided only on the side surface 111y of the coil 111 as illustrated in FIGS. 8B and 8C, and may be provided on the side surface 111y and the lower surface of the coil 111 as illustrated in FIG. 8D. Here, FIGS. 8B and 8C illustrate that the magnetic material is provided between the adjacent two coils 111 and a spacing part, by which the magnetic material is spaced, is provided and is not provided.

Furthermore, as illustrated in FIG. 8E, the magnetic material may be provided only on the upper surface 111x and the side surface 111y of some coils 111 and may not be provided in the remaining coils. When the magnetic part 113 is provided only in some coils 111, the coil 111 provided with the magnetic part 113 and the coil 111 not provided with the magnetic part 113 may be disposed alternately.

Furthermore, a cross-section of the coil 111 may have a circular shape, that is, a shape of a wire as in FIGS. 9A and 9B, the magnetic part 113 may be provided along an outer surface of the coil 111 as a whole even when the cross-section of the coil has a circular shape, or the magnetic part 113 may be provided in some coils but may not be provided in the remaining coils. Furthermore, the coil 111 and the magnetic part 113 may be surrounded by the first insulation part or by the second insulation part without any substrate.

In this way, when the magnetic part 113 is provided on the coil 111, the coil 111 and/or the magnetic part 113 may be provided regularly or irregularly, and distances between the adjacent coils 111 and/or the magnetic part 113 may be the same or different. The magnetic part 113 and the coils 111 may be disposed in various forms, and the disposition of the magnetic part 113 and the coils 111 may be modified according to a thickness of the coils 111, a disposition interval of the coils 111, a disposition form of the coils 111, a material of the magnetic part 113, and a permeability according to the material of the magnetic part 113.

The coil module according to the embodiment of the inventive concept may be manufactured through various methods. Hereinafter, a method of manufacturing the coil module will be described as an example, and various methods of manufacturing a coil module, which will be described below, may be variously combined and modified without departing from the inventive concept.

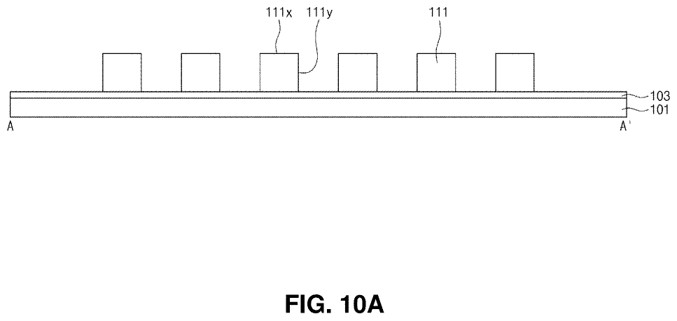

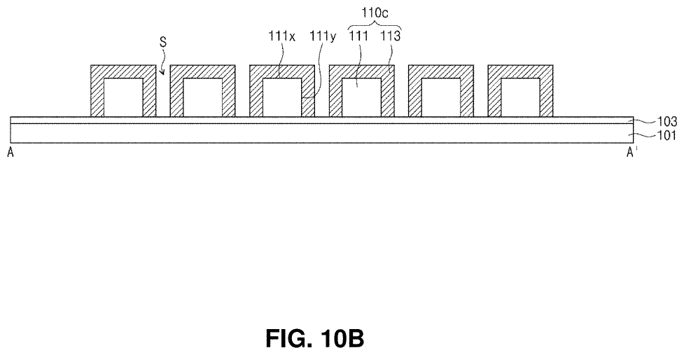

FIGS. 10A and 10B are cross-sectional views schematically illustrating a method of manufacturing a coil module according to an embodiment of the inventive concept.

Referring to FIGS. 10A and 10B, the coil module according to the embodiment of the inventive concept may be manufactured by preparing the substrate 101, forming the coil 111 on the substrate 101, and forming the magnetic part 113 on the coil 111. The magnetic part 113 is manufactured to directly contact the coil 111 and cover at least a portion of the coil 111.

The substrate 101 has a plate shape such that the coil part 110c is provided on at least one surface thereof. The substrate 101 may include a magnetic material having an insulating property.

The insulation part 103 may be additionally provided onto the substrate 101. In the embodiment of the inventive concept, after an operation of preparing the substrate 101, an operation of forming the insulation part 103 onto the substrate 101 may be added. In the following embodiment, it will be described as an example that the insulation part 103 is provided on the substrate 101, and it will be described that only the substrate 101 is provided without any insulation part 103 if necessary. Even when only the substrate 101 is provided, the insulation part 103 may be provided on the upper surface of the substrate 101. The insulation part 103 may be formed in various schemes, such as deposition, coating, lamination, and printing, according to a material thereof.

The coil part 110 is formed on the substrate 101. The method includes an operation of forming the coil 111 on the substrate 101 as illustrated in FIG. 10A, and an operation of forming the magnetic part 113 that covers at least a portion of the coil 111 as illustrated in FIG. 10B.

In the operation of forming the coil part 110c, after the coil 111 is formed first, the magnetic part 113 may be formed next.

The coil 111 may include various conductive materials, and particularly, may include a metallic material, but the inventive concept is not limited thereto.

In order to form the coil 111 on the substrate 101, various methods, for example, plating, deposition, coating, and printing may be used. When plating is used, the coil 111 may be formed by using electro-plating or electroless plating. When deposition is used, the coil 111 may be formed by performing patterning after depositing a metal film on an entire surface of the substrate 101.

The magnetic part 113 is formed to directly contact the coil 111 and cover at least a portion of the coil 111. To achieve this, the magnetic part 113 may be formed on the substrate 101, in which the coil 111 is formed, and patterning may be performed by forming the magnetic part 113 on the entire surface of the substrate 101 by using deposition and the like and then etching the substrate 101 such that the magnetic part 113 has a specific shape, or the magnetic part 113 may be directly formed to have a specific shape without forming the magnetic part 113 on the entire surface of the substrate 101. In the former case, the coil 111 may be manufactured by performing exposure and development by using a photosensitive film, patterning the photosensitive film, and etching a metal film while the patterned photosensitive film as a mask. In the latter case, the coil 111 may be manufactured by making an area, except for an area, in which the coil 111 is to be formed, or performing a selective measure, for example, by applying a current to only an area, in which the coil 111 is to be formed. During the masking, a polymer resin, for example, PET, PI, and PSA may be used.

Furthermore, in addition to the etching, a measure of, for example, controlling presence of the magnetic part 113 on the upper surface of the substrate 101 or a thickness of the substrate 101 may be made by using chemical-mechanical polishing. For example, the upper surface 111x of the coil 111 may be exposed by polishing and removing the magnetic part 113 formed on the upper surface of the coil 111, or a thickness of the magnetic part 113 provided on the upper surface of the coil part 110 may be decreased.

For example, when the magnetic part 113 is formed through the electroless plating, the deposition, and the coating, a masking operation of making the areas of the coil 111, except for an area, in which the magnetic part 113 is to be formed, before the magnetic part 113 is formed. Furthermore, for example, when the magnetic part 113 is formed through the electro-plating, a current may be applied only to the area, in which the magnetic part 113 is to be formed.

When the magnetic part 113 is patterned after the plating or the deposition, the magnetic part 113 may be selectively formed at various locations, including the upper surface, the side surface, or the lower surface of the coil 111.

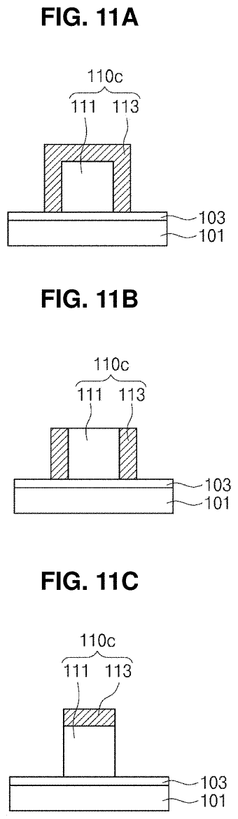

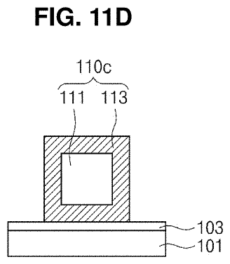

FIGS. 11A to 11D illustrate various shapes that may be manufactured when the magnetic part 113 is formed through plating.

Referring to FIG. 11A, the magnetic part 113 may be formed to cover both of the upper surface 111x and the side surface 111y of the coil 111.

Referring to FIG. 11B, the magnetic part 113 may be formed not on the upper surface 111x of the coil 111 but on the side surface 111y of the coil 111.

Referring to FIG. 11C, the magnetic part 113 may be formed on the upper surface 111x of the coil 111 but not on the side surface 111y of the coil 111.

Referring to FIG. 11D, the magnetic part 113 may be formed to cover both of the upper surface 111x and the side surface 111y of the coil 111, but also may cover the lower surface of the coil 111. The coil 111 may be manufactured by manufacturing the coil 111, in which the magnetic part 113 is formed on the upper surface 111x and the side surface lily thereof, performing a transfer to another substrate 101 such that the lower surface thereof is exposed, and forming the magnetic part 113 on the exposed lower surface. A method of forming the coil part 110 by using transfer will be described below.

Here, although the coil 111 having a wire shape having a circular cross-section is not illustrated, the magnetic part 113 may be formed on the surface of the coil 111 having a wire shape in a scheme of immersing a wire in a plating liquid. Although it is not easy to form the magnetic part 113 only at a portion of the surface of the coil 111 along a circumference of the coil 111 when the coil 111 has a wire shape, the magnetic part 113 may be formed in the same method as the method of forming the magnetic part 113 in the quadrangular coil 111 after the wire is disposed on the substrate 101.

According to the embodiment of the inventive concept, a photosensitive film may be used in a process of patterning after the deposition.

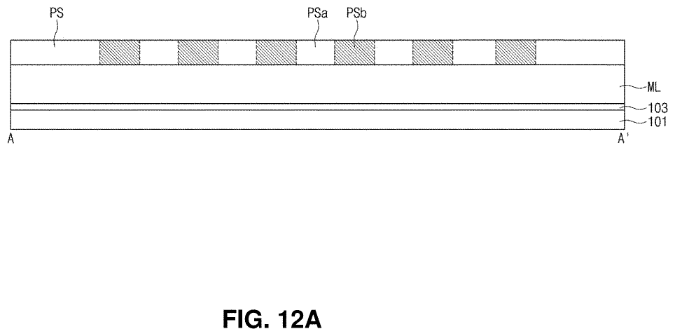

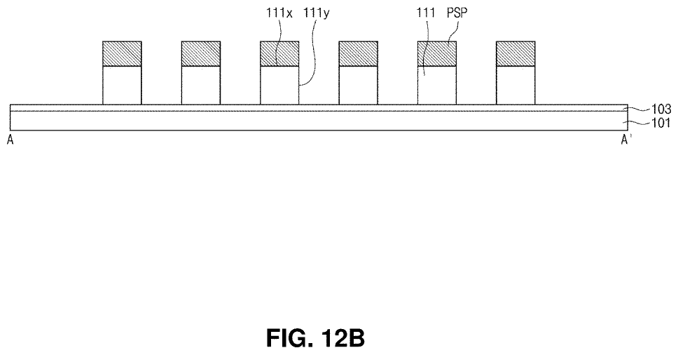

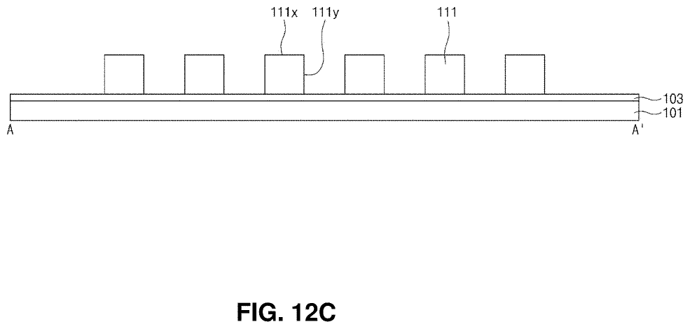

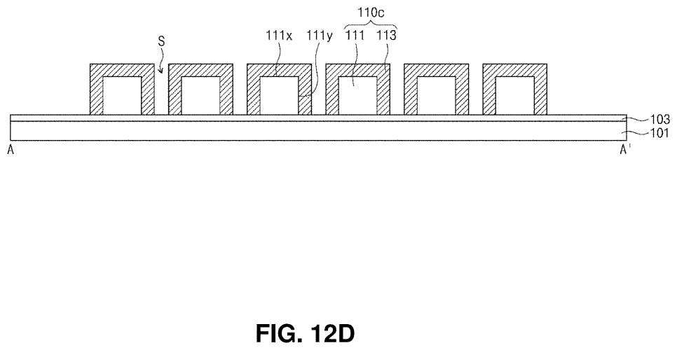

FIGS. 12A to 12D are cross-sectional views schematically illustrating an operation of forming a coil part by using a photosensitive film.

Referring to FIGS. 12A to 12D, the coil part 110 may be manufactured by forming a conductive film ML on the substrate 101 first, forming a photosensitive film pattern PSP by exposing and developing the photosensitive film PS, forming the coil 111 by etching the conductive film ML by using the photosensitive film pattern PSP as a mask, removing the photosensitive film pattern PSP, and forming the magnetic part 113 on the coil 111, from which the photosensitive film pattern PSP is removed.

As disclosed in FIG. 12A, in the present embodiment, the photosensitive film PS may be formed on the substrate 101, in which a metal film is formed through application, but may be manufactured in a form of a photosensitive film to be laminated on the substrate 101.

The photosensitive film selectively reacts specific light (for example, a UV ray), and for example, may be a dry film including a dry film type photoresist. The photosensitive film is a film including a photosensitive material layer, and may be laminated on a metal film. Hereinafter, an example, in which a photosensitive film is used, will be described, and in this case, the same reference numerals will be used.

Thereafter, the photosensitive film PS may be exposed and developed by using a mask (not illustrated). The mask is a slit mask or a refraction mask, and may include a first area that shields all the irradiated light, and a second area that transmits all the irradiated light.

After the exposure, the photosensitive film on the substrate 101 is divided into a first area PSa and a second area PSb according to present of an optical reaction. After the exposed photosensitive film PS is developed, the photosensitive film pattern PSP is formed in an area, in which all light is shielded, and an area, through which all light passes, is completely removed and thus a surface of the metal film is exposed. However, a positive type photosensitive film is used such that the photosensitive film of the exposed portion is removed as described above in the embodiment of the inventive concept, but the inventive concept is not limited thereto, and a negative type photosensitive film capable of removing the photosensitive film at an unexposed portion may be used in another embodiment of the inventive concept.

After the process, as disclosed in FIG. 12B, the coil 111 may be formed by etching and patterning the metal film by using an etching liquid by using the photosensitive film pattern PSP as a mask.

As illustrated in FIG. 12D, the magnetic part 113 may be formed on the formed coil 111. The magnetic part 113 may be formed on a surface of the coil 111 through a process such as plating, deposition, or coating.

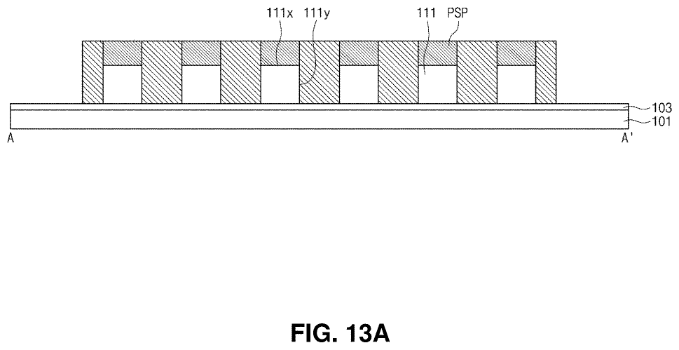

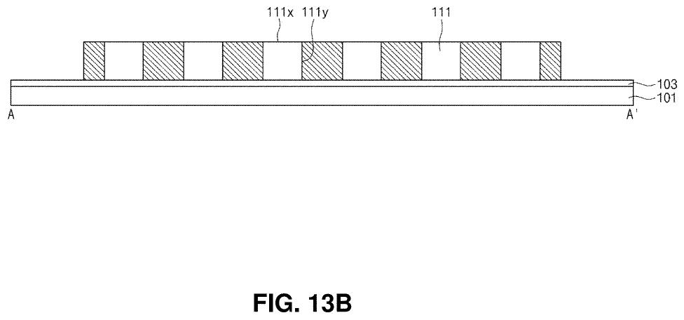

In the embodiment of the inventive concept, when the coil part 110 is formed by using the photosensitive film PS, it is possible to form the coil 111 and the magnetic part 113 in a single process. For example, after the metal film ML is etched by using the photosensitive film pattern PSP, the magnetic part 113 may be formed in a state, in which the photosensitive film pattern PSP is not removed. FIGS. 13A and 13B are cross-sectional views schematically illustrating a part of an operation of forming the coil part 110 by using the photosensitive film.

Referring to FIGS. 13A and 13B, the photosensitive film PS may be provided on the metal film ML, the photosensitive film PS may be exposed and developed (see FIG. 12A), the coil 111 is formed by patterning the metal film while the photosensitive film pattern PSP is taken as a mask (see FIG. 12B), and the upper surface of the substrate 101, in which the photosensitive film pattern PSP is formed, may be plated as illustrated in FIG. 13A. Then, the substrate 101 may be plated such that a gap between the adjacent two metals is filled, or a spacing space is formed between the two metals. For convenience of description, it is illustrated in the drawings that the gap between the two metals is filled with the magnetic part 113.

Next, as illustrated in FIG. 13B, the photosensitive film pattern PSP and the magnetic part 113 on the photosensitive film pattern PSP may be lifted off. By removing only the photosensitive film pattern PSP and the magnetic part 113 on the photosensitive film pattern PSP, only the coil 111, and the magnetic part 113 between adjacent portions of the coil 111 are left, and the final coil part 110c is formed. Here, a spacing part may be provided between the adjacent portions of the coil 111, and a spacing part is provided through an additional patterning process after the photosensitive film pattern and the magnetic part 113 on the photosensitive film pattern are removed.

According to the embodiment of the inventive concept, the coil part 110 may be directly formed on the substrate 101, but may be formed through a method of forming the coil part 110 in a separate auxiliary substrate 101 and then transferring the coil part 110 to the substrate 101.

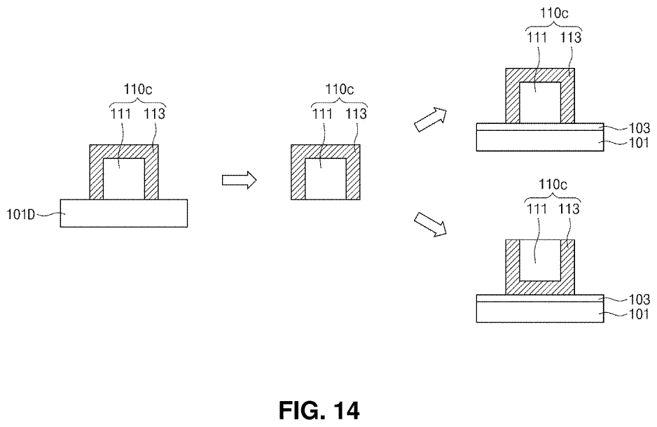

FIG. 14 is a cross-sectional view schematically illustrating a method of forming the coil part 110 by using transfer.

Referring to FIG. 14, the coil 111 and the magnetic part 113 may be formed in a separate temporary substrate 101D. The coil 111 and the magnetic part 113 may be manufactured on the temporary substrate 101D through plating, deposition, coating, printing, and the like.

The temporary substrate 101D may be removed from the coil part 110c, and thus, the coil part 110c, in which the magnetic part 113 is formed, is prepared. The coil part 110 may be used alone, but may be transferred onto the substrate 101 according to the embodiment of the inventive concept. Then, the insulation part 103 may be provided onto the substrate 101. During the transfer, an adhesive may be provided onto the coil part 110 and the insulation part 103 if necessary. Here, when the coil part 110 manufactured in the temporary substrate 101D is converted and is provided onto the substrate 101, the upper surface of the coil part 110 may be exposed to the outside, and the magnetic part 113 may be additionally formed on the upper surface of the coil part 110 if necessary.

As described above, in the coil module according to the embodiment of the inventive concept, the coil part may be manufactured through various methods, and the various methods may be combined without departing from the inventive concept.

In the embodiment of the inventive concept, in the above-described method of manufacturing a coil module, at least some operations may be performed in a Reel to Reel scheme or a panel-to-panel scheme. In particular, at least one of the operation of forming the coil and the operation of forming the magnetic part may be performed in a Reel to Reel scheme or a panel-to-panel scheme. Furthermore, when the coil module is manufactured, the Reel to Reel scheme and the panel-to-panel scheme may be combined to be performed.

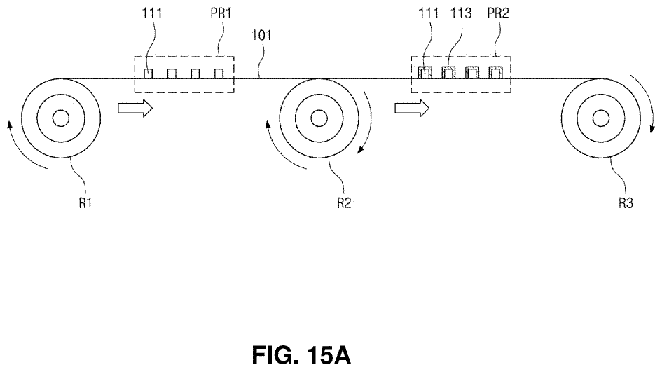

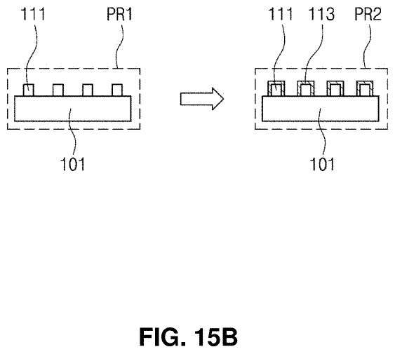

FIGS. 15A and 15B conceptually disclose that a process is performed in a Reel to Reel scheme or a panel-to-panel scheme.

First, referring to FIG. 15A, when the coil module is manufactured, the substrate 101 may be provided in a roll that is wound in one direction, and the wound roll may be unrolled sequentially to perform a specific process. After the process, the treated substrate 101 may be rolled into a roll again. Furthermore, the roll, on which the process has been performed finally, may be cut or broken in unit of coil modules.

In the drawings, for convenience of description, first, an operation of providing a first roll R1, on which the substrate 101 is rolled, performing a first operation PR1 of forming the coil 111 by sequentially unrolling the first roll R1, and rolling a second roll R2, and an operation of performing a second operation PR2 of forming the magnetic part 113 by unrolling the second roll R2 again and rolling the substrate 101 with a third roll R3 are illustrated. Here, the first to third rolls R1 to R3 and the first operation PR1 and the second operation PR2 are illustrates as an example for explaining the Reel to Reel process, an additional operation, in addition to the first operation PR1 and the second operation PR2 may be performed, the substrate 101 may be rolled or unrolled between the first to third rolls R1 to R3, or a specific operation may be performed while any one roll is omitted and a roll is unrolled.

The Reel to Reel scheme also may be applied to a wire of the coil 111 having a circular cross-section. In particular, it is easier to perform a process while the wire is wound.

Referring to FIG. 15B, the substrate 101 is provided not in a rolled form but in a flat panel form, and the second operation PR2 of forming the magnetic part 113 may be performed after the first operation PR1 of forming the coil 111. Here, the panel may be provided to have various sizes and be manufactured simultaneously in a plurality of coil modules, and finally, the roll, on which the process has been performed, may be cut and/or broken in unit of coil modules.

In the embodiment of the inventive concept, the coil module may be modified into various forms, for example, in the connection relationship thereof or the number and disposition of the coils 111, and the coil module may be manufactured by using the above-described method.

The coil module manufactured through the above-described method may be used in an electronic device thereafter. For example, the electronic device may be manufactured by manufacturing the coil module, providing the battery on one side of the coil module, and providing the magnetic sheet between the coil module and the battery.

As described above, according to the embodiment of the inventive concept, various forms of magnetic parts may be easily formed on the coil. Accordingly, the coil module may be easily manufactured. Furthermore, the coil module manufactured through the method may enhance transmission of signals, increase a wireless charging efficiency, and decrease a heat emission temperature in the coil module.

According to the embodiment of the inventive concept, the inventive concept provides a method of manufacturing a wireless charging coil module that has a high wireless charging efficiency while showing an excellent heat dissipation effect when low, middle, or high electric power is wirelessly transmitted and received for a long time.

Although the preferred embodiment of the inventive concept has been described until now, it can be understood by an ordinary person in the art that the inventive concept may be variously corrected and changed without departing from the spirit and area of the inventive concept described in the claims.

Accordingly, the technical scope of the inventive concept is not limited to the contents descried in the detailed description, but should be determined by the claims.

What is claimed is:

1. A method of manufacturing a coil module that receives or transmits electric power or signals wirelessly by using an electromagnetic field, the method comprising:
preparing a substrate;
forming a coil on the substrate; and
forming a magnetic part covering at least a portion of the coil while directly contacting a surface of the coil, and configured to act as an electromagnetic booster that enhances an intensity of the electromagnetic field generated on the surface of the coil,
wherein the magnetic part decreases, among a skin effect of an eddy current and a proximity effect generated in the coil, the proximity effect by isolating electric power in a gap of the coil that is rotated in the one direction.

2. The method of claim 1, wherein the forming of the magnetic part is performed through at least one of electroless plating, electro-plating, deposition, coating, and printing.

3. The method of claim 2, wherein when the magnetic part is formed through the at least one of the electroless plating, the electro-plating, the deposition, the coating, and the printing, masking a coil area, except for an area, in which the magnetic part is to be formed, is performed in advance before the forming of the magnetic part.

4. The method of claim 3, wherein when the magnetic part is formed through the electro-plating, a current is applied to only the area, in which the magnetic part is to be formed.

5. The method of claim 2, further comprising:
polishing the magnetic part formed on an upper surface of the coil to remove the magnetic part.

6. The method of claim 1, wherein the forming of the coil and the forming of the magnetic part are performed in a single process.

7. The method of claim 6, wherein the forming of the coil and the magnetic part includes:
forming a conductive film on the substrate;
forming a photosensitive film on the conductive film;
forming a photosensitive film pattern by exposing and developing the photosensitive film; and
forming the coil by etching the conductive film while the photosensitive film pattern is taken as a mask.

8. The method of claim 7, further comprising:
forming the magnetic part on the substrate; and
lifting off the photosensitive film pattern and the magnetic part on the photosensitive film pattern.

9. The method of claim 7, wherein the photosensitive film is provided as a dry film type photoresist.

10. The method of claim 1, further comprising:
removing the substrate from the coil and the magnetic part; and
transferring the coil and the magnetic part onto a separate substrate.

11. The method of claim 1, wherein at least one of the forming of the coil and the forming of the magnetic part is performed in a Reel to Reel scheme.

12. The method of claim 1, wherein at least one of the forming of the coil and the forming of the magnetic part is performed in a panel-to-panel scheme.

13. The method of claim 1, wherein the magnetic part covers at least a portion of an upper surface and a side surface of the coil.

14. The method of claim 1, wherein the magnetic part provided between adjacent portions of the coil has a spacing part between the adjacent portions of the coil.

15. The method of claim 1, wherein a cross-section that is perpendicular to a lengthwise direction of the coil has a wire shape, and the magnetic part covers an entire outer peripheral surface of the coil.

16. The method of claim 1, wherein in the coil arranged in the first direction, the magnetic part is provided alternately.

17. The method of claim 1, wherein the magnetic part includes at least one of a metal pallet, a nano crystal, an amorphous material, a metal-based or ferrite pellet, a ferrite complex, a sendust pallet, and a sendust complex.

18. The method of claim 17, wherein the magnetic part includes a combination of two or three or more elements selected from a group consisting of Fe, Ni, Co, Mn, Al, Zn, Cu, Ba, Ti, Sn, Si, Sr, P, B, N, C, W, Cr, Bi, Li, Y, and Cd.

19. The method of claim 1, wherein the substrate is a rigid printed circuit board, a flexible printed circuit board, or a rolled copper printed circuit board.

20. The method of claim 1, wherein the coil is provided as a winding, and the coil includes at least one of a copper coil, a multiline coil, a laminated ceramic condenser coil, a low-temperature simultaneous co-fired ceramic coil, and a ceramic winding coil.
